(19) United States
(12) Patent Application Publication
(10) Pub. No.: US 2018/0351403 A1
(43) Pub. Date: Dec. 6, 2018

(54) EMBEDDED MAGNETIC FIELD INDICATOR ARRAY FOR DISPLAY OF UNIFOMITY OR BOUNDARY OF MAGANETIC FIELD

(71) Applicant: Intel Corporation, Santa Clara, CA (US)

(72) Inventors: Songnan Yang, San Jose, CA (US); Karim H. Tadros, Santa Clara, CA (US); Yee Wei Hong, Santa Clara, CA (US); Shengzhen Zhang, Shanghai (CN); Hong W. Wong, Portland, OR (US)

(73) Assignee: Intel Corporation, Santa Clara, CA (US)

(21) Appl. No.: 15/778,085

(22) PCT Filed: Dec. 26, 2015
(86) PCT No.: PCT/US2015/000375

§ 371 Date: May 22, 2018

(51) Int. Cl. H02J 50/10; G01R 33/02; H02J 7/00; H02J 7/02; H05B 37/00; H01F 38/14

(52) U.S. Cl. CPC H02J 50/10; G01R 33/02; H01F 38/14; H02J 7/025; H05B 37/00; H02J 7/0047

(57) ABSTRACT

Methods and apparatus relating to embedded magnetic field indicator array for display of uniformity or boundary of magnetic field are described. In an embodiment, a diode is coupled to a coil in series. The coil receives wireless energy from a wireless power transmitter and generates an electrical current in response to the receipt of the wireless energy to cause the diode to emit light. The coil is to be formed by at least two coil loops (which may be spiral or overlapping). Other embodiments are also disclosed and claimed.

### FIELD

The present disclosure generally relates to the field of electronics. More particularly, an embodiment relates to embedded magnetic field indicator array for display of uniformity or boundary of magnetic field.

### BACKGROUND

Inductive or magnetic resonance wireless charging devices are emerging as a promising technology to replace traditional wired chargers for portable computing devices. During operation a wireless charging device generates a magnetic field which is invisible to the naked human eye.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a magnetic field indicator array used to visualize the size and/or location of two charging fields, according to some embodiments.

FIG. 2 illustrates a single magnetic field indicator cell and a magnetic field indicator array, according to some embodiments.

FIG. 3 illustrates a comparison of a magnetic field indicator array with complete and partial diode activation, according to some embodiments.

FIG. 4 illustrates three-dimensional and cross sectional view of a graph of a sample magnetic field generated by a wireless transmitter, which could be used to provide additional features in some embodiments.

FIG. 5 shows a magnetic field indicator unit cell design, according to an embodiment.

FIG. 6 illustrates a graph indicating the behavior of the field indicator of FIG. 5 at different locations of a magnetic field, according to an embodiment.

FIG. 7 illustrates various configurations for unit cells, according to some embodiments.

FIGS. 8 and 9 illustrate block diagrams of embodiments of systems, which may be utilized in various embodiments discussed herein.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware, software, firmware, or some combination thereof.

As mentioned above, wireless charging systems generate a magnetic field during operation which is invisible to the naked human eye. This property however can pose a significant problem with identifying the location and size of a charging field generated by the wireless charging system. To this end, some embodiments provide an embedded magnetic field indicator array for display of uniformity and/or boundary of the magnetic field.

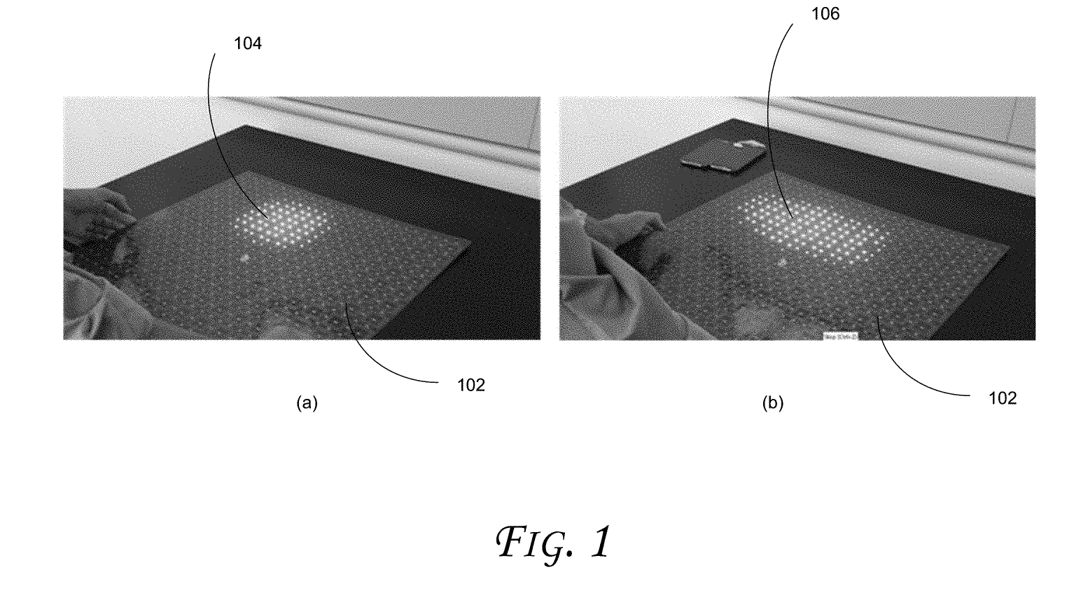

More particularly, FIG. 1 illustrates a magnetic field indicator array 102 used to visualize the size and location of two charging fields 104 and 106, according to some embodiments. As shown in FIG. 1(a), the magnetic field 104 may be smaller in size (and/or location) when compared with the magnetic field 106 of FIG. 1(b). According, the magnetic field indicator array 102 may provide a visible visual aid for magnetic fields 104/106 generated by a wireless charging station, when such fields would be otherwise invisible to the naked human eye. In an embodiment, the array 102 may utilize LEDs (Light Emitting Diodes) to provide a visual indication regarding the location and size of magnetic fields.

Moreover, FIG. 1 shows a magnetic field indicator array in action where two different size wireless charging/power transmitters have been installed under a table and the array is able to indicate the location and/or size of the active area of the charging field. Furthermore, the magnetic field indicator array 102 can be a powerful marketing tool as it delivers the concept of wireless charging magnetic field intuitively through visual effects. It may also be used to assist in installation and/or operation of a wireless charging device (e.g., to determine the location for a charging transmitter). For example, array 102 may assist in placement of a charging transmitter during installation where no visual marks are available. Also, array 102 may be used after installation of the charging transmitter (where no visual marks are available regarding the location of the transmitter) to allow for correct placement (or location marking) of where a device to be charged is to be positioned within the generated magnetic field.

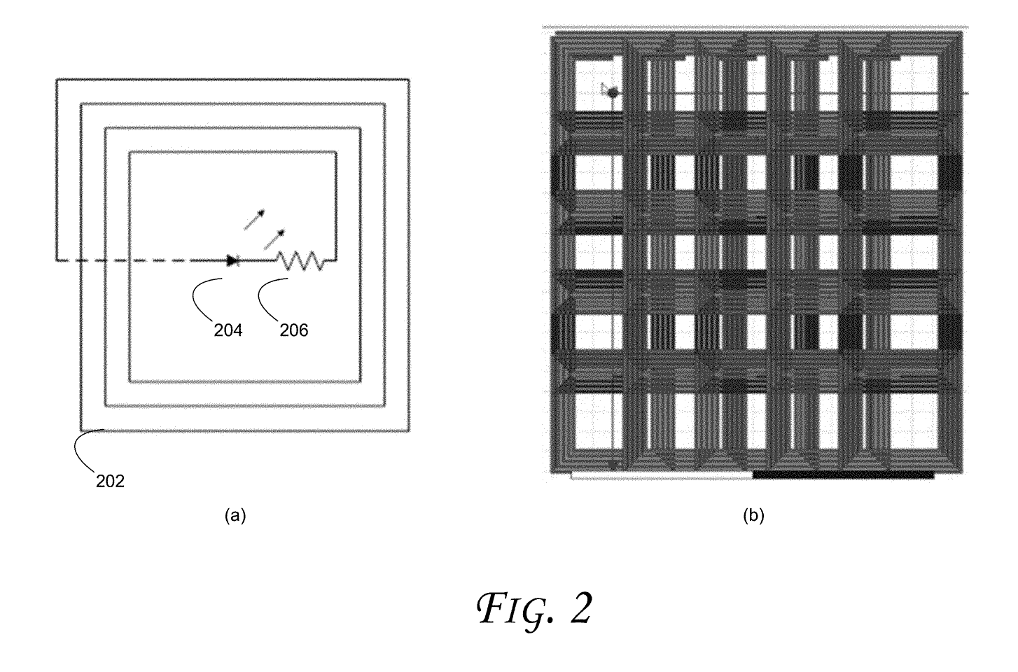

FIG. 2 illustrates a single magnetic field indicator cell and a magnetic field indicator array, according to some embodiments. More specifically, a single magnetic field indicator cell is shown in FIG. 2(a), and a sample magnetic field indicator array is shown in FIG. 2(b). The array of FIG. 2(b) may be constructed by coupling a plurality of the single magnetic field indicator cells of FIG. 2(a), e.g., in a grid fashion. The magnetic field indicator array of FIG. 2(b) may be the same or similar to the array 102 of FIG. 1.

Moreover, FIG. 2(a) shows the schematic view of a single unit cell of a magnetic field indicator, which consists of a spiral coil 202, a single diode 204 (e.g., an LED), and a series resistance 206. Once the indicator is presented to an AC (Alternating Current) magnetic field perpendicular to the spiral coil 202, the alternating magnetic field is going to induce AC voltage across the diode 204 and resistor 206. The diode 204 is turned on when the AC voltage has the correct/matching polarity (or phase), while the series resistance 206 may control the electrical current flow through the diode 204 to protect the diode and/or control the brightness of the diode. The unit cell of FIG. 2(a) can be tiled into an array/grid form with partial overlapping unit cells to form an array (shown in FIG. 2(b)), where when presented to the active charging field, the diodes coupled to a coil that resides in the active magnetic field area would receive sufficient induced voltage/energy to turn on and emit light.

In some embodiments, a wireless charging transmitter product may be installed and/or debugged by utilizing the magnetic field indicator array 102. Moreover, since an indicator array with LED design lights up by partially rectifying the induced AC voltage, as the LED turns on, it may also generate significant harmonics, which in turn contribute to EMI (Electro Magnetic Interference) emissions. Since the LED array indicates the entire active area by lighting up all LEDs inside (or physically proximate to) the active magnetic area, the harmonics generated by an individual LED accumulates to a high level of EMI, e.g., to the point that the magnetic field indicator array may provide spurious emissions.

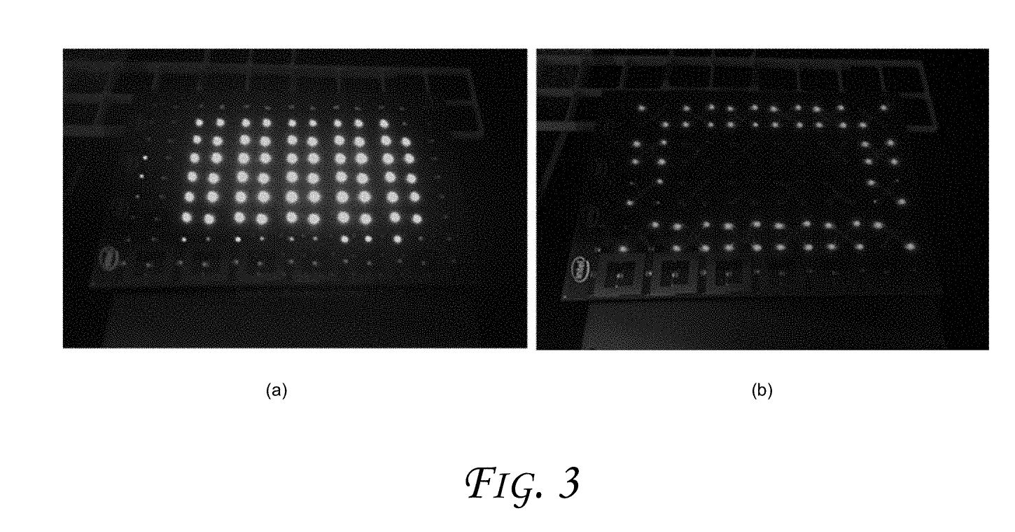

To this end, an embodiment provides a new magnetic field indicator design that leverages a unique unit cell coil design (such as shown in FIG. 3) to effectively reduce EMI radiation while supporting the same or similar features as other designs (such as discussed with reference to FIGS. 1-2). More particularly, to mitigate excessive EMI generated by a magnetic field indicator array. A unique unit cell coil design is used which selectively lights up one or more LEDs at the edge(s) or at corner(s) proximate to the active magnetic area. Since less LEDs are needed to indicate the boundary of the active area(s), the effective EMI generation by the LEDs is significantly reduced.

In particular, FIG. 3 illustrates a comparison of a magnetic field indicator LED array with complete and partial LED activation, according to some embodiments. The unit cell of magnetic field indicator in FIG. 3(b) is designed to light up at the locations/areas where the magnetic field has the maximum differential. When this unit cell is configured into an array and presented to the wireless charging surface, unlike the design of FIG. 3(a), it will indicate the boundary of the charging field. As shown in FIG. 3, both type of LED field indicator arrays may be used to visualize the charging magnetic field generated by a wireless charging transmitter. As can be seen in FIG. 3, the design of FIG. 3(a) lights up all the LEDs within the active area, while the design of FIG. 3(b) indicates the boundary of the active charging area, which significantly reduces the number of LEDs that needs to be turned on by the field, and as a result reduce the cumulative EMI effects or emissions.

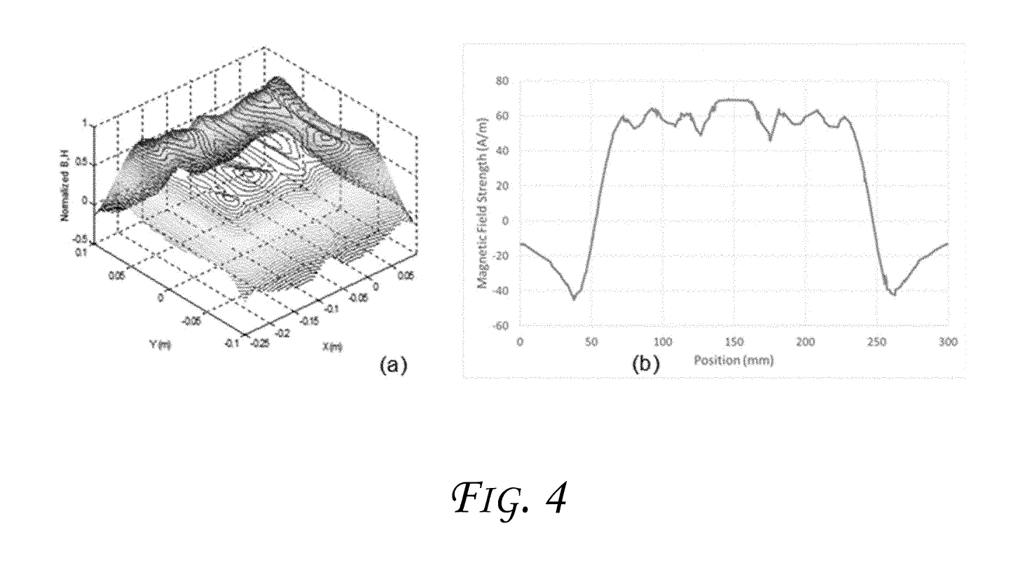

FIG. 4 illustrates three-dimensional and cross sectional view of a graph of a sample magnetic field generated by a wireless charging transmitter, which could be used to provide improvements to some embodiments. More particularly, FIG. 4(a) shows the perspective view of typical magnetic distribution generated by a wireless charging transmitter. As can be seen in the wireless charging active area, the field generated is relatively uniform. But there is usually a sharp drop off of field along the edge of the active area. FIG. 4(b) shows the cross section view of the same field distribution, where it can be seen that outside of active area, beyond the sharp drop off, the magnetic field generated has s reverse direction (opposite sign as the field inside active area). To this end, some embodiments leverage this change in field direction along the edge of active area to provide a unique unit cell coil for field indicator to enable visualization of the boundary of the active magnetic area.

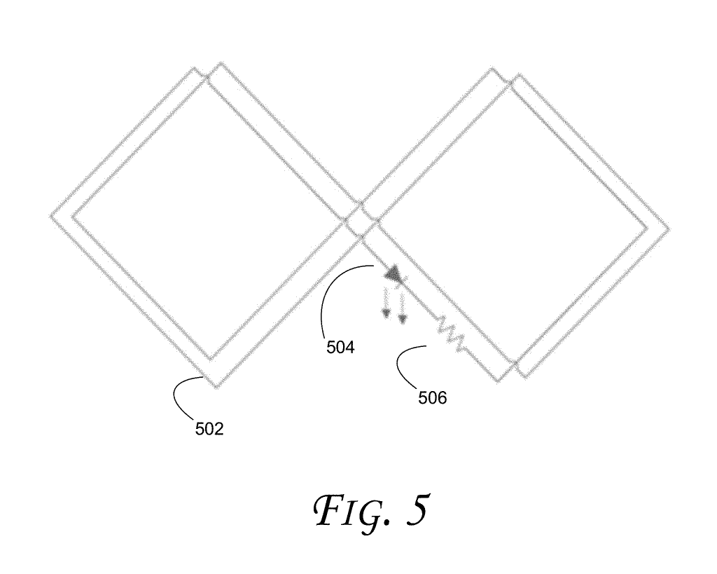

FIG. 5 shows a magnetic field indicator unit cell design, according to an embodiment. As shown, the coil 502 may include two halves with opposite sense of rotation. As illustrated, the two halves/loops of the coil may physically overlap at a mid-section (without making electrical contact). When introduced to a charging surface, the AC magnetic field induces two AC voltages on the two halves/loops of the coil and applied to the (e.g., LED) diode 504 in series with the coil (and a series resistance 506).

In accordance with an embodiment, one unique feature of this FIG. 5 design is that when both halves of the coil are subjected to the same magnetic field, due to the out of phase combination of the two loops/halves, the induced voltage across the diode 504 is canceled. Alternatively, when the field applied to the two halves of the coil is opposite in polarity, the combined induced voltage across the diode is maximized by the combination of the induced voltages. This unique feature allows the LED to receive enough voltage to light up when placed across the boundary of the magnetic field generated by a wireless transmitter coil.

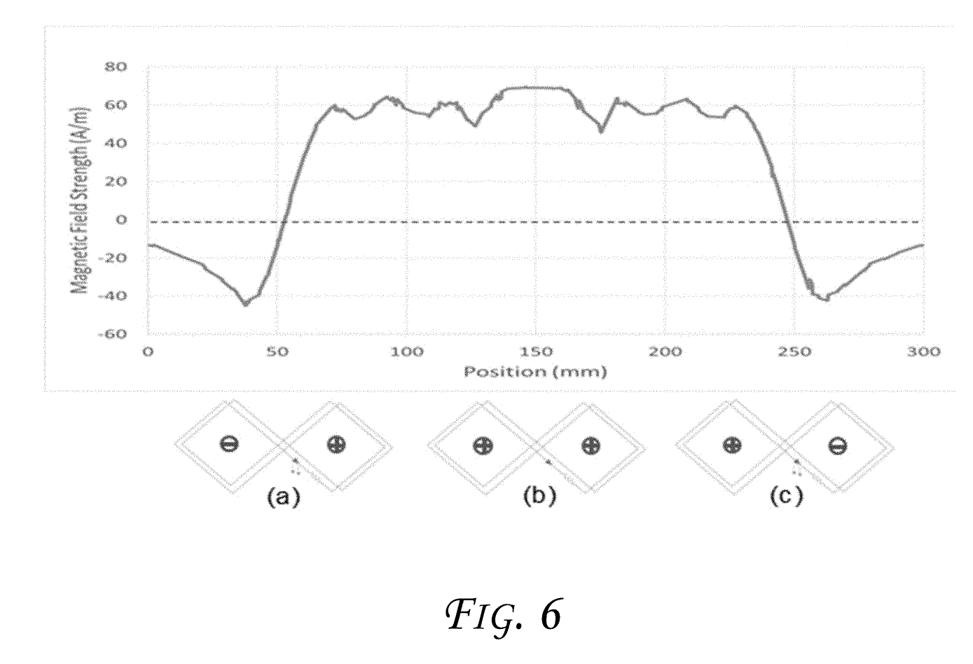

FIG. 6 illustrates a graph indicating the behavior of the field indicator of FIG. 5 at different locations of a magnetic field, according to an embodiment. More particularly, as shown in FIG. 6(b), when the proposed field indicator is placed inside the active area, both halves are exposed to the field with the same sign/polarity. As a result, the induced voltages across the diode 504 cancel each other and the diode does not light up. In the case of FIG. 6(a) and (c), since the field indicator sits on the boundary of the magnetic field (where the sharp drop off and transition in field direction occurs), the field captured by the two halves of the coil 502 have opposite signs/polarity. The large differential in voltage induced on two halves of the coil presents higher combined AC voltage across the diode to light it up.

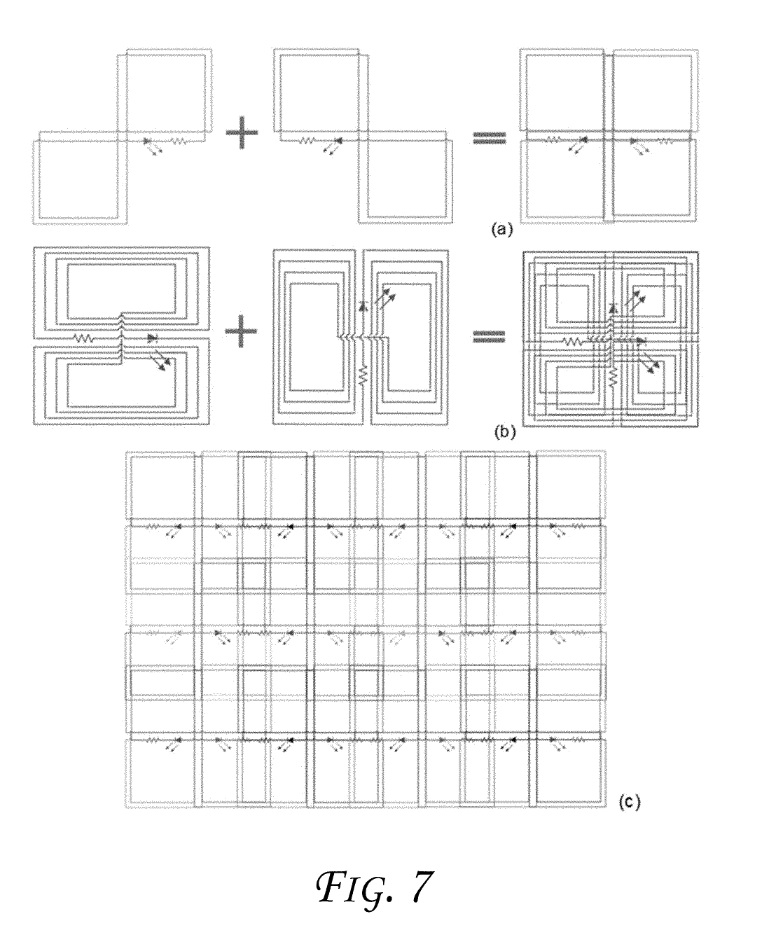

FIG. 7 illustrates various configurations for unit cells, according to some embodiments. More particularly, FIG. 7(a) shows construction of a two dimensional unit cell, FIG. 7(b) shows an alternative implementation of a two dimensional unit cell, FIG. 7(c) shows a two dimensional magnetic field boundary indicator array based on unit cell of FIG. 7(a). For example, an orthogonal pair of coils can be added to capture the boundary along arbitrary directions, as shown in FIG. 7(a). Alternative unit cell design following the embodiment of FIG. 5 may be used as a unit cell of field boundary indicator, as shown in FIG. 7(b). The field indicator unit cell may be tiled to form an array to visualize the entire boundary of the wireless charging active area, as shown in FIG. 7(c).

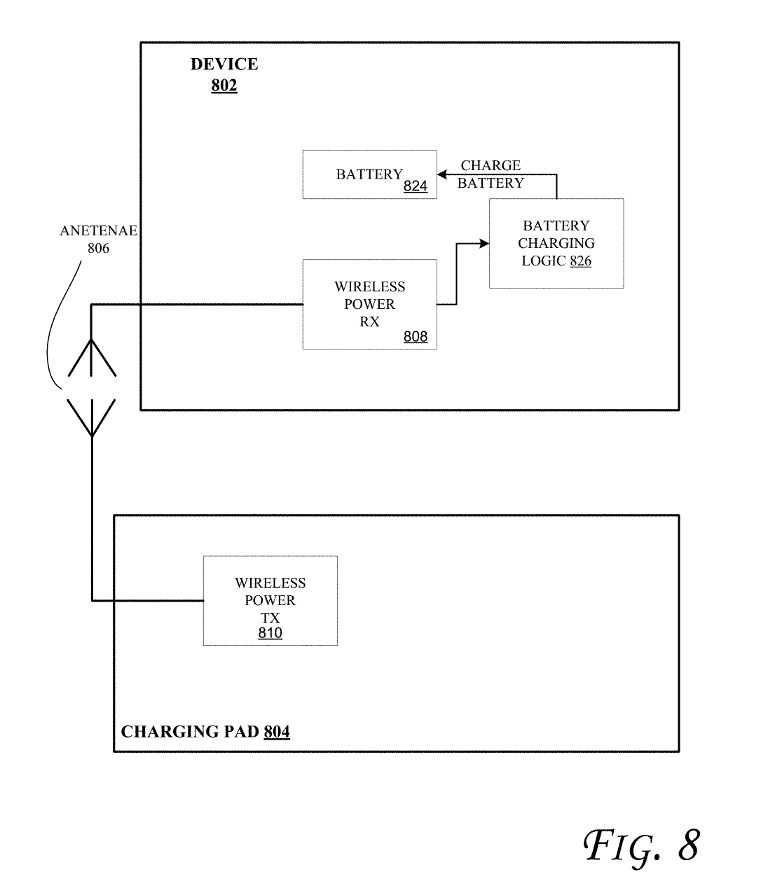

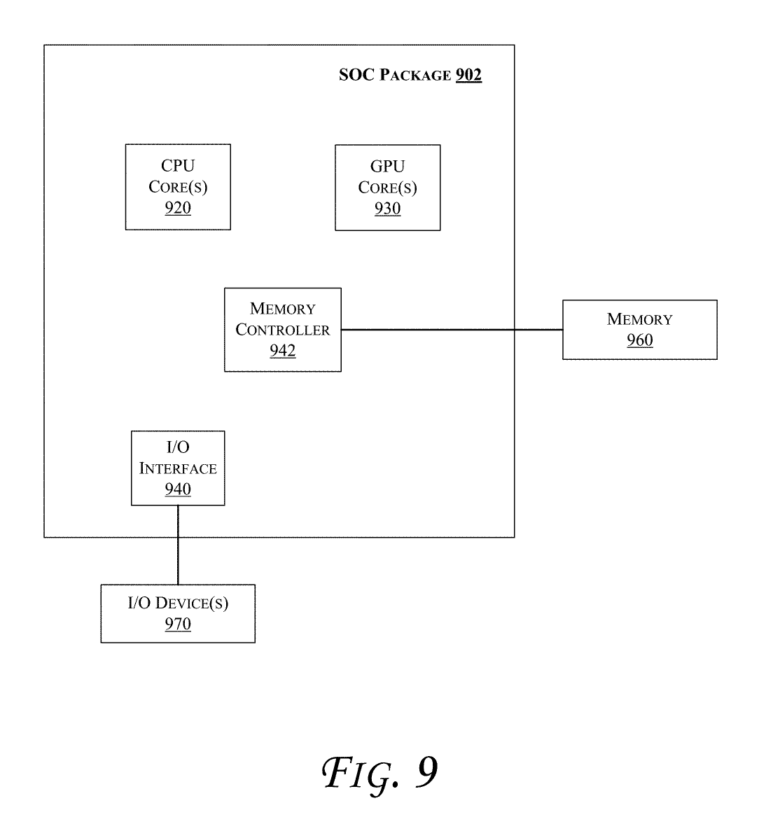

FIG. 8 shows a block diagram of a computing system 800 with wireless charging capability, according to an embodiment. In an embodiment, indicator array discussed with reference to any of the previous figures may be used to visually display the magnetic field generated by components of system 800 (e.g., by the charging pad 804). System 800 includes a device 802 and a charging pad 804. Antennae 806 (e.g., at least one for each device 802 and pad 804) enable wireless transmission of electromagnetic energy/waves from the charging pad 804 to the device 802 to allow for wireless charging. In an embodiment, device 802 is incorporated into a computing device, such as a mobile or portable computing device. The portable computing device may be a 2:1 system, smartphone, tablet, UMPC (Ultra-Mobile Personal Computer), laptop computer, Ultrabook™ computing device, wearable devices (such as smart watch, smart glasses, smart bracelets, and the like (such as those discussed with reference to FIG. 9). The battery 824 of the device 802 (and/or the wireless power received via wireless power receiver 808 or from battery charging logic 826) may then be used to provide power to (or assist in charging) the portable computing device.

As shown in FIG. 8, device 802 includes a wireless power receiver (RX) 808 to receive electromagnetic waves (through one of antennae 806 directly coupled to the RX 808) and charging pad 804 includes a wireless power transmitter (TX) 810 to transmit the electromagnetic waves (through one of antennae 806 directly coupled to TX).

Also, the computing devices discussed herein (e.g., device 802) that are capable of being charged via wireless charging can be embodied as a System On Chip (SOC) device. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus. Also, the SOC package 902 may include more or less components, such as those discussed herein with reference to the other figures. Further, each component of the SOC package 920 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 via the memory controller 942. In an embodiment, the memory 960 (or a portion of it) can be integrated on the SOC package 902. Further, the I/O interface 940 may be coupled to one or more I/O devices 970, e.g., via an interconnect and/or bus. I/O device(s) 970 may include one or more of a keyboard, a mouse, a touchpad, a display, an image/video capture device (such as a camera or camcorder/video recorder), a touch screen, a speaker, or the like.

The following examples pertain to further embodiments. Example 1 includes an apparatus comprising: a diode coupled to a coil in series, wherein the coil is to receive wireless energy from a wireless power transmitter, wherein the coil is to generate an electrical current in response to the receipt of the wireless energy to cause the diode to emit light, wherein the coil is to be formed by at least two coil loops comprising a first coil loop and a second coil loop. Example 2 optionally includes the apparatus of example 1, wherein the diode is to be coupled to one of the first coil loop or the second coil loop in series. Example 3 optionally includes the apparatus of any one of examples 1-2, wherein the first coil loop and the second coil loop are to be coupled in series. Example 4 optionally includes the apparatus of any one of examples 1-3, wherein the first coil loop and the second coil loop are to overlap at a mid-section without establishment of an electrical contact between the first coil loop and the second coil loop at the mid-section. Example 5 optionally includes the apparatus of any one of examples 1-4, wherein the coil is to generate the electrical current to cause the diode to emit light in response to a difference between a first induced voltage in the first coil loop and a second induced voltage in the second coil loop. Example 6 optionally includes the apparatus of any one of examples 1-5, wherein the first coil loop and the second coil loop are orthogonal. Example 7 optionally includes the apparatus of any one of examples 1-6, wherein the coil is to comprise at least four coil loops, wherein each pair of the at least four coil loops are to be orthogonal. Example 8 optionally includes the apparatus of any one of examples 1-7, wherein the coil is to comprise a spiral coil. Example 9 optionally includes the apparatus of any one of examples 1-8, wherein the diode is to comprise a light emitting diode. Example 10 optionally includes the apparatus of any one of examples 1-9, wherein the diode is coupled in series with a resistor, wherein the resistor is to control an electrical current flow through the diode. Example 11 optionally includes the apparatus of any one of examples 1-10, wherein the diode is coupled in series with a resistor, wherein the resistor is to control an electrical current flow through the diode to protect the diode. Example 12 optionally includes the apparatus of any one of examples 1-11, wherein the diode is coupled in series with a resistor, wherein the resistor is to control an electrical current flow through the diode to control brightness of light to be emitted by the diode. Example 13 optionally includes the apparatus of any one of examples 1-12, further comprising a plurality of cells, wherein each of the plurality of cells is to be formed by the diode and the coil, wherein the plurality of cells are to be coupled in a grid configuration, wherein each of the plurality of diodes is to be coupled in series with a corresponding coil, wherein each corresponding coil is to cause a corresponding diode from the plurality of diodes to emit light in response to receipt of the wireless energy at the corresponding coil. Example 14 optionally includes the apparatus of any one of examples 1-13, further comprising a plurality of cells, wherein each of the plurality of cells is to be formed by the diode and the coil, wherein the plurality of cells are to be coupled in a grid configuration, wherein at least two of the plurality of cells are to at least partially overlap. Example 15 optionally includes the apparatus of any one of examples 1-14, further comprising a plurality of cells, wherein each of the plurality of cells is to be formed by the diode and the coil, wherein all diodes of the plurality of cells that are proximate to magnetic field, to be generated by the wireless energy, are lit. Example 16 optionally includes the apparatus of any one of examples 1-15, further comprising a plurality of cells, wherein each of the plurality of cells is to be formed by the diode and the coil, wherein a portion of diodes of the plurality of cells that are proximate to a periphery of a magnetic field, to be generated by the wireless energy, are lit.

Example 17 includes a system comprising: a battery to supply power to one or more components; a diode coupled to a coil in series, wherein the coil is to receive wireless energy from a wireless power transmitter, wherein the coil is to generate an electrical current in response to the receipt of the wireless energy to cause the diode to emit light, wherein the coil is to be formed by at least two coil loops comprising a first coil loop and a second coil loop. Example 18 optionally includes the system of example 17, wherein the diode is to be coupled to one of the first coil loop or the second coil loop in series. Example 19 optionally includes the system of any one of examples 17-18, wherein the first coil loop and the second coil loop are to be coupled in series. Example 20 optionally includes the system of any one of examples 17-19, wherein the diode is to comprise a light emitting diode. Example 21 optionally includes the system of any one of examples 17-20, wherein the first coil loop and the second coil loop are to overlap at a mid-section without establishment of an electrical contact between the first coil loop and the second coil loop at the mid-section. Example 22 optionally includes the system of any one of examples 17-21, wherein the coil is to generate the electrical current to cause the diode to emit light in response to a difference between a first induced voltage in the first coil loop and a second induced voltage in the second coil loop. Example 23 optionally includes the system of any one of examples 17-22, wherein the first coil loop and the second coil loop are orthogonal. Example 24 optionally includes the system of any one of examples 17-23, wherein the coil is to comprise at least four coil loops, wherein each pair of the at least four coil loops are to be orthogonal.

Example 25 includes a method comprising: coupling a diode to a coil in series, wherein the coil receives wireless energy from a wireless power transmitter, wherein the coil generates an electrical current in response to the receipt of the wireless energy to cause the diode to emit light, wherein the coil is formed by at least two coil loops comprising a first coil loop and a second coil loop. Example 26 optionally includes the method of example 25, further comprising coupling the diode to one of the first coil loop or the second coil loop in series. Example 27 optionally includes the method of any one of examples 25-26, further comprising coupling the first coil loop and the second coil loop in series. Example 28 optionally includes the method of any one of examples 25-27, wherein the diode comprises a light emitting diode. Example 29 optionally includes an apparatus comprising means to perform a method as set forth in any one of examples 25 to 27.

Example 30 includes an apparatus comprising means to perform a method as set forth in any preceding example. Example 31 comprises machine-readable storage including machine-readable instructions, when executed, to implement a method or realize an apparatus as set forth in any preceding example.

In various embodiments, the operations discussed herein, e.g., with reference to FIGS. 1-9, may be implemented as hardware (e.g., logic circuitry), software, firmware, or combinations thereof, which may be provided as a computer program product, e.g., including a tangible (e.g., non-transitory) machine-readable or computer-readable medium having stored thereon instructions (or software procedures) used to program a computer to perform a process discussed herein. The machine-readable medium may include a storage device such as those discussed with respect to FIGS. 1-9.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1-25. (canceled)

26. An apparatus comprising:
a diode coupled to a coil in series,
wherein the coil is to receive wireless energy from a wireless power transmitter, wherein the coil is to generate an electrical current in response to the receipt of the wireless energy to cause the diode to emit light, wherein the coil is to be formed by at least two coil loops comprising a first coil loop and a second coil loop.

27. The apparatus of claim 26, wherein the diode is to be coupled to one of the first coil loop or the second coil loop in series.

28. The apparatus of claim 26, wherein the first coil loop and the second coil loop are to be coupled in series.

29. The apparatus of claim 26, wherein the first coil loop and the second coil loop are to overlap at a mid-section without establishment of an electrical contact between the first coil loop and the second coil loop at the mid-section.

30. The apparatus of claim 26, wherein the coil is to generate the electrical current to cause the diode to emit light in response to a difference between a first induced voltage in the first coil loop and a second induced voltage in the second coil loop.

31. The apparatus of claim 26, wherein the first coil loop and the second coil loop are orthogonal.

32. The apparatus of claim 26, wherein the coil is to comprise at least four coil loops, wherein each pair of the at least four coil loops are to be orthogonal.

33. The apparatus of claim 26, wherein the coil is to comprise a spiral coil.

34. The apparatus of claim 26, wherein the diode is to comprise a light emitting diode.

35. The apparatus of claim 26, wherein the diode is coupled in series with a resistor, wherein the resistor is to control an electrical current flow through the diode.

36. The apparatus of claim 26, wherein the diode is coupled in series with a resistor, wherein the resistor is to control an electrical current flow through the diode to protect the diode.

37. The apparatus of claim 26, wherein the diode is coupled in series with a resistor, wherein the resistor is to control an electrical current flow through the diode to control brightness of light to be emitted by the diode.

38. The apparatus of claim 26, further comprising a plurality of cells, wherein each of the plurality of cells is to be formed by the diode and the coil, wherein the plurality of cells are to be coupled in a grid configuration, wherein each of the plurality of diodes is to be coupled in series with a corresponding coil, wherein each corresponding coil is to cause a corresponding diode from the plurality of diodes to emit light in response to receipt of the wireless energy at the corresponding coil.

39. The apparatus of claim 26, further comprising a plurality of cells, wherein each of the plurality of cells is to be formed by the diode and the coil, wherein the plurality of cells are to be coupled in a grid configuration, wherein at least two of the plurality of cells are to at least partially overlap.

40. The apparatus of claim 26, further comprising a plurality of cells, wherein each of the plurality of cells is to be formed by the diode and the coil, wherein all diodes of the plurality of cells that are proximate to magnetic field, to be generated by the wireless energy, are lit.

41. The apparatus of claim 26, further comprising a plurality of cells, wherein each of the plurality of cells is to be formed by the diode and the coil, wherein a portion of diodes of the plurality of cells that are proximate to a periphery of a magnetic field, to be generated by the wireless energy, are lit.

42. A system comprising:
a battery to supply power to one or more components;
a diode coupled to a coil in series,
wherein the coil is to receive wireless energy from a wireless power transmitter, wherein the coil is to generate an electrical current in response to the receipt of the wireless energy to cause the diode to emit light, wherein the coil is to be formed by at least two coil loops comprising a first coil loop and a second coil loop.

43. The system of claim 42, wherein the diode is to be coupled to one of the first coil loop or the second coil loop in series.

44. The system of claim 42, wherein the first coil loop and the second coil loop are to be coupled in series.

45. The system of claim 42, wherein the diode is to comprise a light emitting diode.

46. A method comprising:
coupling a diode to a coil in series,
wherein the coil receives wireless energy from a wireless power transmitter, wherein the coil generates an electrical current in response to the receipt of the wireless energy to cause the diode to emit light, wherein the coil is formed by at least two coil loops comprising a first coil loop and a second coil loop.

47. The method of claim 46, further comprising coupling the diode to one of the first coil loop or the second coil loop in series.

48. The method of claim 46, further comprising coupling the first coil loop and the second coil loop in series.
